(19) United States
(12) Patent Application Publication
(10) Pub. No.: US 2018/0077816 A1
(43) Pub. Date: Mar. 15, 2018

(54) ARRANGEMENT AND AIR GUIDANCE

(71) Applicant: FUJITSU LIMITED, Kawasaki-shi (JP)

(72) Inventor: Gerhard Mühsam, Königsbrunn (DE)

(73) Assignee: FUJITSU LIMITED, Kawasaki-shi (JP)

(21) Appl. No.: 15/688,235

(22) Filed: Aug. 28, 2017

(30) Foreign Application Priority Data
Sep. 15, 2016 (DE) 102016117394.0

(51) Int. Cl. H05K 7/14; H05K 7/20; G11B 33/12

(52) U.S. Cl. CPC H05K 7/1488; G11B 33/126; H05K 7/20727

(57) ABSTRACT

The invention relates to an arrangement comprising a server housing with a mounting cage for a server component. The mounting cage comprises an insertion opening for the insertion of the server component in an insertion direction. The mounting cage comprises an air opening inside the server housing on at least one side adjacent to the insertion opening. The arrangement further comprises an air guidance, which is inserted into the mounting cage, so that an air flow is limited along the insertion direction by the mounting cage. Here, air can flow out of an inner space of the server housing or flow into the inner space of the server housing.

The invention further relates to an air guidance for such an arrangement.

The invention relates to an arrangement and an air guidance for an arrangement.

Servers such as rack servers for a server rack comprise a server housing with specific housing dimensions, which typically limit dimensions of components and properties of the server. Components for such a server must comply with a height specification for the server, e.g. one rack unit (RU), for example.

The cooling of the installed components may present a further problem in such servers. Fans that blow air from one side of the server in the direction of an opposite side of the server are provided to that end. In this case, the air passes over installed components and is discharged at a rear side of the server. However, due to components at the rear side of such a server, it is not possible to have the entire rear side of the server open, so that the air can stream out of the server in an unobstructed manner. Rather, air openings, e.g. in the form of holes, are provided at the rear side of the server. The same applies to the front of the server, where such components are installed. Fresh air is pulled-in through air openings at the front of the server, e.g. holes, to ensure cooling of the components.

In this case, the size and number of such openings determine an air flow resistance. A lower flow resistance allows a faster air stream (German “Luftstrom, English also: “air flow”) in the server and thus a better cooling of components in the server.

One object of the invention is to provide an improved cooling concept for servers.

According to a first aspect, the object is achieved by an arrangement which includes a server housing of a server, the server housing having a mounting cage for a server component. The mounting cage comprises an insertion opening for the insertion of the server component in an insertion direction. Inside the server housing, the mounting cage comprises an air opening on at least one side adjacent to the insertion opening. Furthermore, the arrangement includes an air guidance which is inserted in the mounting cage so that an air stream through the mounting cage is limited along the insertion direction. In this case, air can stream out of an inner space of the server housing through the air opening of the mounting cage and the insertion opening or can be pulled into the inner space of the server housing.

The air opening in the mounting cage increases a surface area of the already existing air openings on a side of the server housing where the insertion opening of the mounting cage is located. Once the (variable) air guidance has been inserted in the mounting cage, the side of the mounting cage facing the inner space of the server housing is closed in such a way that no significant air stream, in particular no air stream at all, can stream out or in through the mounting cage. To that end, air can stream out of the inner space of the server housing through the air opening through the mounting cage and the air guidance. In addition to the openings already present at the rear side of the server, this presents an additional opening for air. One advantage here is that the air, which is guided through the mounting cage and the air guidance out of the inner space of the server housing, can be discharged from a certain region, adjacent to the mounting cage in the inner space of the server housing, in a targeted manner. In this way, the air flow resistance is reduced in this region and a better cooling performance is achieved. The arrangement of the air opening in the mounting cage and the air guidance does not only achieve a reduction of the flow resistance, which causes an improved cooling performance of components in the inner space of the server housing, but components arranged in the region of the air opening can also be cooled in a particularly efficient manner, since an increased air stream, e.g. an air stream having a lower flow resistance, is present in the region of the air opening.

In this case, a frame in which server components such as hard disks or in particular power supply units (PSU) are inserted, can be used as a mounting cage. If multiple mounting cages for redundant PSUs are provided in such a server housing, e.g. a server housing for a rack server, and if no PSU is required, the above described arrangement and the air guidance in the mounting cage allow improving the cooling performance in the server housing.

According to an advantageous configuration, a size of the air opening of the mounting cage is selected such that a predetermined flow resistance can be set.

The size of the air opening can be configured in such a way that the air flow resistance through the inner space of the server is reduced in an advantageous manner. If, for example, the opening is selected too large, this results in a loss of streaming air at another point in the server housing. However, if the air opening is selected too small in the mounting cage, the effect would possibly be neglectable. A suitable selection of the size of the air opening improves the flow resistance-reducing effect and thus the cooling performance for the server. Such an adjustment can be effected depending on one or multiple of the following parameters: size of the server housing, components installed in the server housing (in particular their size, flow resistance and arrangement), already existing air openings of the server housing (in particular in its rear side, or front), performance of the fans.

According to a further advantageous configuration, the air opening of the mounting cage has a grid structure.

The air opening can either be an individual hole or have a grid structure. In the case that the air opening has a grid structure, this corresponds to multiple individual openings next to one another and/or one over the other in the mounting cage. Thus, the comprising of a grid structure on the air opening is equivalent to a plurality of individual air openings in the mounting cage. However, the grid structure provides advantages here. For example, a rigidity of the mounting cage is maintained. An individual, large hole in the mounting cage can impair the stability of the mounting cage and/or of the server housing. A further advantage of the grid structure lies with the possibility of adjusting the flow resistance through the air opening, given a predetermined surface area, over which air is to stream. If, for example, air is to stream-out over half of the side of the mounting cage, but the flow resistance is to be reduced only in such a way like an air opening would cause over a third or a quarter of the side of the mounting cage, the surface area of the air opening that accounts for half the size of the side of the mounting cage can be reduced by the grid structure, so that the flow resistance is adjusted accordingly.

According to a second aspect of the invention, the object is achieved by an air guidance for an arrangement within a mounting cage of a server housing of a server. The air guidance includes a hollow body having a rear wall and an open side opposite the rear wall. Furthermore, the air guidance has a (second) air opening, which is arranged between the rear wall and the open side, so that air can stream through the second air opening and the open side.

The configuration of the air guidance as a hollow body allows a simple mounting in the mounting cage. In this case, the size of the hollow body is correspondingly adapted to the size of the server component for which the mounting cage was originally provided. Thus, the air guidance can be plugged or inserted in the mounting cage, which simplifies the mounting process. The air guidance comprises a second air opening, which is arranged in such a way that it is arranged to be aligned with the air opening of the mounting cage when the air guidance is inserted in the mounting cage.

For example, the air opening can be achieved by omitting one side of the air guidance or by a hole in one side of the air guidance.

According to an advantageous configuration, the second air opening has a grid structure.

The second air opening can be a hole with a grid structure, as described above with respect to the air opening of the mounting cage. The second air opening is arranged such that either the air streaming through the air opening of the mounting cage is not obstructed, or that the above described flow resistance is achieved by the interplay of the air opening of the mounting cage and the second air opening. An offset arrangement of two holes may also serve for that purpose.

According to further advantageous configurations, the second air opening is arranged at a distance from the rear wall and/or from the open side.

The configuration and placement of the second air opening on the hollow body of the air guidance can be selected in such a way that flow properties can advantageously be used.

According to a further advantageous configuration, the air guidance comprises at least one retaining bracket for fixing the air guidance to the mounting cage of the server housing.

The air guidance may comprise a retaining bracket or a plurality of retaining brackets, which simplify the fixing of the air guidance in or to the mounting cage. For example, latch hooks or clamping lugs can be provided, which engage, latch or brace with, in or on walls of the mounting cage. This allows preventing the air guidance from slipping out of the mounting cage.

According to a further advantageous configuration, a size of the second air opening is selected such that a predetermined flow resistance can be set when the air guidance is arranged in the mounting cage.

According to a further advantageous configuration, the air guidance is arranged in the mounting cage of the server housing in such a way that the second air opening of the air guidance is arranged aligned or flush with the air opening of the mounting cage, so that air can stream out of the inner space of the server housing through the air opening of the mounting cage, the second air opening of the air guidance and the open side of the air guidance or stream into the inner space of the server housing through the open side of the air guidance, the second air opening of the air guidance and the air opening of the mounting cage.

A flow resistance can be set by an overlap of the air opening and the second air opening, for example. In addition, or as an alternative, the flow resistance can be adjusted via a thick grid structure in one or both air openings.

The invention will hereinafter be explained in greater detail using exemplary embodiments and figures. The figures show in:

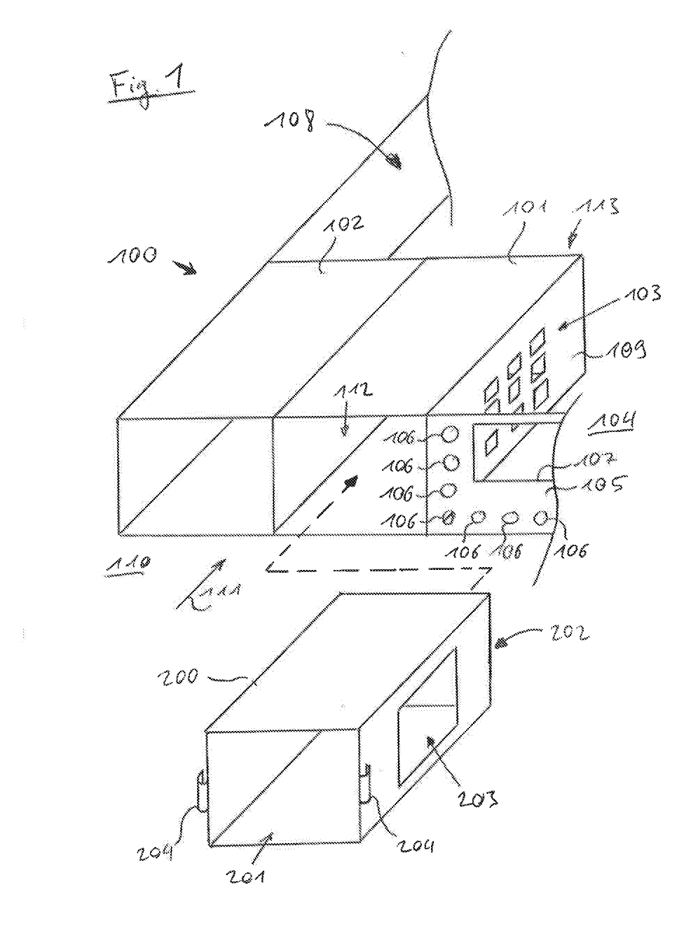

FIG. 1 a schematic illustration of a part of a server housing having an air guidance according to one embodiment of the invention,

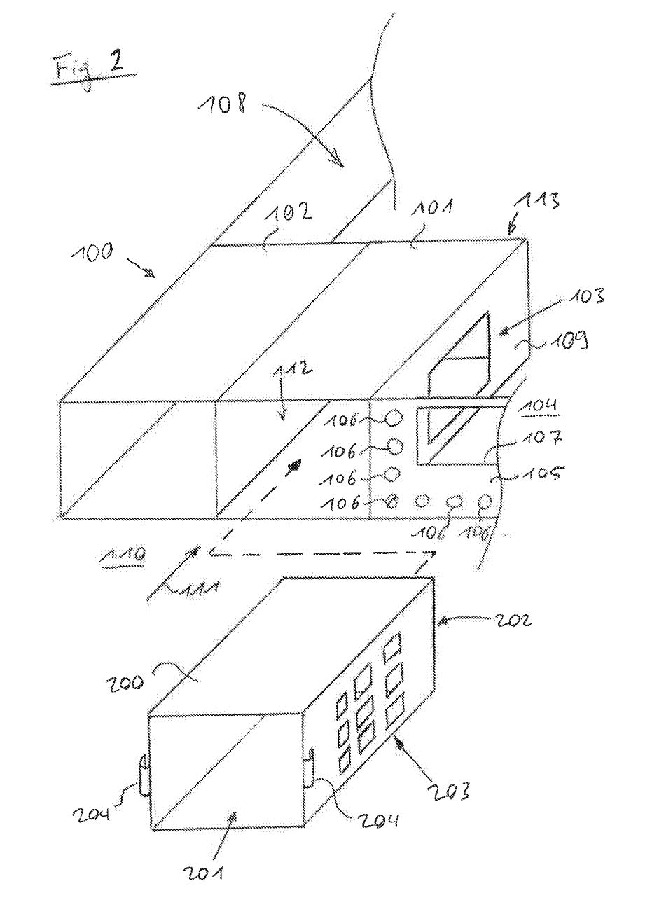

FIG. 2 a schematic illustration of a part of a server housing having an air guidance according to another embodiment of the invention,

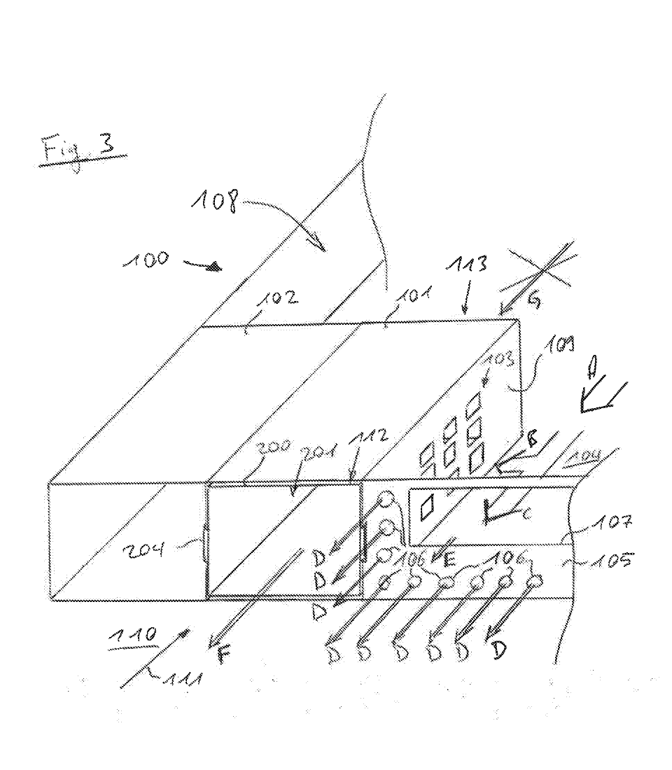

FIG. 3 a schematic illustration of an arrangement of an air guidance in a server housing according to the embodiment of FIG. 1, and

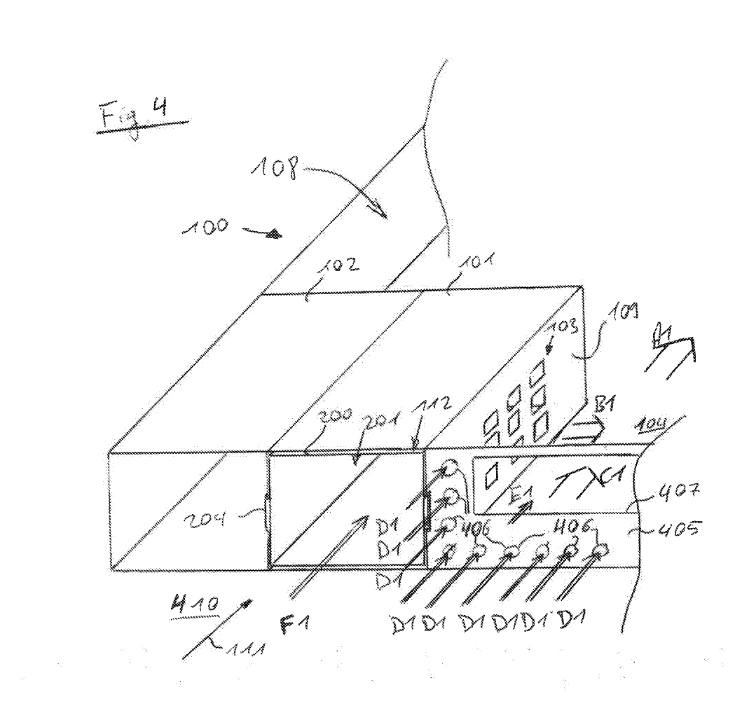

FIG. 4 a schematic illustration of an arrangement of an air guidance in a server housing according to another embodiment of the invention.

Like reference characters are used for elements having the same functions throughout the various figures. However, this is not to be understood as a limitation.

FIG. 1 shows a schematic view of a server housing 100. The server housing 100 may be a housing of a rack server, which is 1 RU in height, for example. However, the server housing 100 can also be a housing for a different server such as a blade server or a rack server with multiple rack units, or a tower server.

The server housing 100 comprises one mounting cage 101 and a further mounting cage 102. The mounting cages 101, 102 are configured to receive in each case one power supply unit (PSU). This is advantageous for security-relevant servers requiring a redundant power supply. In alternative embodiments, the mounting cages 101,102 can also be mounting cages for a hard disk or other server components. Just as well, two or more different mounting cages can be used, e.g. a mounting cage for a PSU and a mounting cage for a hard disk.

The server housing comprises an inner space 108. All components, fans and expansion components are arranged in this space. The server housing 100 comprises a rear-side cover 105. The cover 105 has multiple openings 106, which are configured to let air pass from the inner space 108 of the server housing 100 to the outside. Hereinafter, a region of the inner space 108, in which components are arranged and which is located in the region of the cover 105, is referred to as a free inner space 104, in which air can stream. One side of the mounting cage 101 is adjacent to the mounting cage 102. Another side 109 of the mounting cage 101 opposite this side is adjacent to the free inner space 104 of the server housing 100. At this side, the mounting cage 101 has an air opening 103. In the exemplary embodiment shown in FIG. 1, the air opening 103 includes multiple individual openings, which are separated from one another by a grid structure.

The mounting cage 101 and the mounting cage 102 are each open on the opposite sides both on a server housing outer side 110 and toward the inner space 108. The server components (not shown) can be inserted in the mounting cages 101, 102 from the outer side 110 of the server housing 100. Thus, an insertion direction 111 is defined from this rear side toward the inner space 108 of the server housing 100. These two sides 112, 113 of the mounting cage 101 in the insertion direction 111 are open and include an insertion opening 112. In other words, the mounting cages 101, 102 are open toward the outer side 110 of the server housing 100, so that one server component can each be inserted in the mounting cage 101 and the mounting cage 102. In order to contact the server component in the server (i.e. in the inner space 108 of the server housing 100), the mounting cage 101, 102 is in each case also open on the side 113 facing the inner space 108 and located opposite the insertion opening 112.

The openings 106 of the cover 105 are configured to let air pass in particular from the free inner space 104 of the server housing 100 toward the outside and let fresh air stream into the housing, respectively. Furthermore, the cover 105 comprises a component opening 107. In the case that this component opening 107 is not fitted with a component, air may exit the free inner space 104 through this opening as well.

Components are arranged in the inner space 104. For example, capacitors, memory modules, energy storages, or other components are arranged here. To cool these components, fans (not shown for the sake of simplicity) are arranged in the server housing 100, which blow air out from the inner space 108 of the server housing 100 through the free inner space 104 and from the openings 106 and, if the latter is not occupied, also through the component opening 107. When streaming over the components in the free inner space 104, the cooling air absorbs waste heat of the components in the server housing 100 and transports it to the outside through the openings 106 and the component opening 107.

In a conventional arrangement (not shown), both mounting cages 101, 102 are fitted with components. For example, in each case one PSU is located in the mounting cage 101 and in the mounting cage 102. An air opening 103 is not provided in this conventional arrangement. Said opening would be covered by the PSU in the mounting cage 101 anyway. The cooling air can escape from the server housing 100 merely through the opening 106 and possibly the component opening 107 in the cover 105. As a result, depending on the performance of the fans, a flow resistance is provided by the overall surface area at the openings and the cover 105.

A lower flow resistance leads to a better flow of the cooling air and thus improves the cooling performance for the server. In order to lower the air resistance, an increase in the surface area, in particular in the overall surface area of all openings 106, is possible. If the openings 106 are designed to be larger or the number of openings 106 is increased, this may reduce the flow resistance. However, the maximum possible surface area of the openings 106 is limited due to the construction of the server housing 100.

In the exemplary embodiment according to FIG. 1, the flow resistance of the cooling air can be further reduced since the air opening 103 is arranged in the mounting cage 101. This is possible when the mounting cage 101 is not occupied or, in an alternative embodiment, is only partly occupied (e.g. by a smaller component that does not completely occupy the mounting cage 101). In the case that the mounting cage 101 is not occupied, it is open toward the inner space 108 of the server housing 100, both at the side opposite the server housing 100 and by the air opening 103.

In order to guide the air in the server housing 100 in an advantageous manner, the air guidance 200 is provided. The air guidance 200 includes a hollow body, in particular a hollow cuboid. The air guidance 200 comprises an open side 201 and a rear wall 202. The rear wall 202 is closed so that the rear wall 202 represents a barrier for air. In contrast, air can freely stream through the open side 201.

Furthermore, the air guidance 200 comprises a second air opening 203. Air flowing into the air guidance 200 through the second air opening 203 can escape from the air guidance 200 through the open side 201.

The air guidance 200 comprises two retaining brackets 204. The retaining brackets 204 are used to secure the air guidance 200 to the server housing 100, in particular to walls of the mounting cage 101. In an alternative embodiment, the air guidance 200 merely comprises one retaining bracket or multiple retaining brackets. The dashed arrow in FIGS. 1 and 2 indicates how the air guidance 200 can be inserted into the mounting cage 101.

If, in the inserted state, the second air opening 203 is located behind the air opening 103 in a manner as to be aligned with the air flow direction, effective opening results from arranging the air opening 103 and the second air opening 203 one over the other.

The effective opening determines the change of the flow resistance of the air from the inner space 108 of the server housing 100 out of the server housing 100. Of course, in alternative embodiments, further constellations and configurations of the air opening 103 and the second air opening 203 are possible. Thus, one or both air openings 103, 203 can be formed as a slot and/or round and/or be arranged offset to one another, for example, so that merely part of the entire respective air opening 103, 203 is located one over the other so as to be aligned or flush with the respective other air opening 203, 103, thus allowing to adjust a flow resistance.

FIG. 2 shows an alternative configuration of the arrangement. The embodiment according to FIG. 2 is different from the above described embodiment in that the air opening 103 does not have a grid structure, but in contrast, the second air guidance 203 has a grid structure. In this case, the effective opening is identical to the effective opening of the embodiment of FIG. 1.

Hereinafter, the functioning of the arrangement having the air guidance 200 is described by means of FIG. 3. FIG. 3 shows a schematic illustration of the configuration according to FIG. 1. However, the air guidance 200 is inserted into the mounting cage 101. In other words, the rear wall 202 closes the side of the mounting cage 101 facing the inner space 108 of the server housing 100 so that no air, or no significant amount of air, can escape therethrough. As used herein, the term “significant amount” refers to an amount that contributes to the cooling of the components in the server housing 100 to a measurable extent.

The second air opening 203 is located aligned behind the air opening 103 of the mounting cage 101 in such a way that air can stream out of the server housing 100 from the free inner space 104 through the air opening 103 and the second air opening 203 through the air guidance 200 and the open side 201.

The two retaining brackets 204 engage around walls of the mounting cage 101. This is merely schematically shown in FIG. 3, which is not a physically correct drawing. The retaining brackets 204 secure the air guidance 200 to the side walls of the mounting café 101 by a clamping effect. In an additional or alternative configuration, the retaining brackets 204 secure the air guidance to the mounting cage 101 and/or to the cover 105 and/or to a further wall of the server housing 100 by clamping and/or latching-in and/or latching.

The air guidance 200 is held in the mounting cage 101 by the retaining brackets 204 in such a way that the air guidance can not slip out.

Flow directions are indicated by arrows A to G in FIG. 3. Arrow A is a main flow direction which leads in the entire inner space 108 of the server housing 100 from the fans (not shown) to the rear side 110 of the server housing 110 in the direction of the openings 106 and the cover 105.

Arrows B and C show a partition of the air stream of arrow A. The air in the direction of arrow B streams through the air opening 103, the air in the direction of arrow C streams in the direction of the cover 105. Just like in a conventional server housing, air streams in the direction of arrow C through the openings 106 (shown by arrows D). Depending on whether the component opening 107 is used or not or how tight it is closed, air will stream therethrough as well (arrow E). The air along the flow direction of arrow B, which streams through the air opening 103 and thus also through the second air opening 203, exits the air guidance 200 via the open side 201 in the direction of arrow F.

The side 113 of the mounting cage 101 facing inward can be closed by the rear wall 202 of the air guidance 200 in an air-tight manner (i.e. tight enough that no significant air stream contributing to the cooling of the components can stream through this side). Thus, no air can exit via the side 113 of the mounting cage 101 opposite the insertion opening 112. This is indicated by the crossed-out arrow G.

An increased cooling effect of the components arranged in the free inner space 104 is thus achieved in multiple ways. On the one hand, components arranged near the mounting cage 101 are cooled more by the air stream in the direction of arrow B. In addition, an air stream in the direction of arrow G is prevented, so that the air of this region behind the mounting cage 101 is additionally possible as an air stream around the mounting cage 101 and in the direction of arrows B and C. This increases the effective amount of air that streams via the free inner space 104 in the region of arrows B and C. Moreover, an additional cooling effect is achieved in that the flow resistance for the main air stream A is reduced. The reduced flow resistance causes that the cooling air can leave the server housing 100 in an easier manner and thus can advantageously transport the waste heat of the components arranged in particular in the free inner space 104, out of the housing 100.

FIG. 4 shows another exemplary embodiment. As described in FIG. 3, flow directions are shown by arrows A1 to F1.

In contrast to the exemplary embodiment of FIG. 3, the exemplary embodiment of FIG. 4 shows an arrangement in which the mounting cages 101, 102 are arranged on a front of the server housing 100.

Fresh air for cooling the server is pulled in from an outer side 410. Incidentally, fresh air is pulled in through openings 406 (arrows D1), which are arranged on a front cover 405 of the server housing 100. Just as well, fresh air can be pulled in through a component opening 407 (arrow E1), which is configured in such a way, for example, that a console terminal, a display device or even another server component can be arranged in the component opening 407. The air flows along arrows D1 and E1 merge into one common air stream along arrow C in the inner space 108, in particular in the free inner space 104.

Furthermore, fresh air can stream in through the open side 201 of the air guidance 200 (arrow F1). The air streaming therethrough is prevented from freely streaming through the mounting cage 101 by the rear wall 202. Rather, the fresh air that streams in is guided by the air guidance 200 through the second air opening 203 and thus through the air opening 103 of the mounting cage 103. This air stream streaming in will then stream in the direction of arrow B2 in to the inner space 108 of the server housing 100. Components can be cooled on the free inner space 104 there before the air streams through the server housing 100 (arrow A1) and fans (not shown) arranged there, possibly cools further components and exits the server housing 100 on a rear side of the server housing 100, which is not shown in FIG. 4.

### LIST OF REFERENCE CHARACTERS

100 Server housing
101, 102 Mounting cage
103 Air opening
104 Free inner space
105, 405 Cover
106, 406 Opening
107, 407 Component opening
108 Inner space
109 Side
110, 410 Outer side
111 Insertion direction
112 Insertion opening
113 Side
200 Air guidance
201 Open side
202 Rear wall
203 Second air opening
204 Retaining bracket
A, B, C, D, E, F, G Arrows, flow direction
A1, B1, C1, D1 Arrows, flow direction
E1, F1, G1 Arrows, flow direction

1. Arrangement, comprising
a server housing of a server with a mounting cage for a server component, wherein the mounting cage comprises an insertion opening for the insertion of the server component in an insertion direction and an air opening inside the server housing on at least one side adjacent to the insertion opening, and
an air guidance, which is inserted into the mounting cage, so that an air flow through the mounting cage is limited along the insertion direction,
wherein air can flow out of an inner space of the server housing or flow into the inner space of the server housing through the air opening of the mounting cage and the insertion opening.

2. Arrangement according to claim 1, wherein a size of the air opening of the mounting cage is selected such that a predefined flow resistance can be adjusted.

3. Arrangement according to claim 1, wherein the air opening of the mounting cage has a grid structure.

4. Air guidance for an arrangement within a mounting cage of a server housing of a server, the air guidance comprising a hollow body having
a rear wall, and
an open side opposite the rear wall, and
an air opening, which is arranged between the rear wall and the open side,
so that air can flow through the air opening and the open side,
wherein the air guidance is arranged to be inserted in an insertion opening of the mounting cage of the server housing for the insertion of a server component in the mounting cage of the server housing in an insertion direction, such that with the air guidance inserted into the mounting cage an air flow through the mounting cage is limited along the insertion direction, whereas air can flow out of an inner space of the server housing or flow into the inner space of the server housing through the open side of the air guidance, the air opening of the air guidance and an air opening of the mounting cage inside the server housing on at least one side adjacent to the insertion opening of the mounting cage.

5. Air guidance according to claim 4, wherein the air opening has a grid structure.

6. Air guidance according to claim 4, wherein the air opening is arranged at a distance to the rear wall.

7. Air guidance according to claim 4, wherein the air opening is arranged at a distance to the open side.

8. Air guidance according to claim 4, wherein the air guidance comprises at least one retaining bracket for fixing the air guidance on the mounting cage of the server housing.

9. Air guidance according to claim 4, wherein a size of the air opening is selected such that a predefined flow resistance can be adjusted if the air guidance is arranged in the mounting cage.

10. Air guidance according to claim 5, wherein a size of the air opening is selected such that a predefined flow resistance can be adjusted if the air guidance is arranged in the mounting cage.

11. Arrangement comprising
a server housing of a server with a mounting cage for a server component, wherein the mounting cage comprises an insertion opening for the insertion of the server component in an insertion direction and an air opening inside the server housing on at least one side adjacent to the insertion opening, and
an air guidance, which is inserted into the mounting cage, so that an air flow through the mounting cage is limited along the insertion direction,
wherein the air guidance comprises a hollow body having
a rear wall, and
an open side opposite the rear wall, and
an air opening, which is arranged between the rear wall and the open side,
so that air can flow through the air opening and the open side, and
wherein the air guidance is arranged in the mounting cage of the server housing in such a manner that the air opening of the air guidance is arranged aligned with the air opening of the mounting cage, so that air can flow out of the inner space of the server housing through the air opening of the mounting cage, the air opening of the air guidance and the open side of the air guidance or flow into the inner space of the server housing through the open side of the air guidance, the air opening of the air guidance and the air opening of the mounting cage.

12. Arrangement according to claim 11, wherein a size of the air opening of the mounting cage is selected such that a predefined flow resistance can be adjusted.

13. Arrangement according to claim 11, wherein the air opening of the mounting cage has a grid structure.

14. Arrangement according to claim 11, wherein the air opening of the air guidance has a grid structure.

15. Arrangement according to claim 11, wherein a size of the air opening of the air guidance is selected such that a predefined flow resistance can be adjusted.

16. Arrangement according to claim 12, wherein a size of the air opening of the air guidance is selected such that a predefined flow resistance can be adjusted.

17. Arrangement according to claim 13, wherein a size of the air opening of the air guidance is selected such that a predefined flow resistance can be adjusted.

18. Arrangement according to claim 14, wherein a size of the air opening of the air guidance is selected such that a predefined flow resistance can be adjusted.

19. Arrangement according to claim 11, wherein the air guidance is fixed on the mounting cage of the server housing via at least one retaining bracket.
